(19) United States
(12) Patent Application Publication
(10) Pub. No.: US 2012/0206685 A1
(43) Pub. Date: Aug. 16, 2012

(54) SEMICONDUCTOR DEVICE, LIQUID CRYSTAL DISPLAY DEVICE HAVING SEMICONDUCTOR DEVICE, AND METHOD FOR PRODUCING SEMICONDUCTOR DEVICE

(75) Inventors: Satoru TAKASAWA, Sammu-shi (JP); Masanori SHIRAI, Sammu-shi (JP); Satoru ISHIBASHI, Sammu-shi (JP)

(73) Assignee: ULVAC, INC.,, Chigasaki-shi (JP)

(21) Appl. No.: 13/402,120

(22) Filed: Feb. 22, 2012

Related U.S. Application Data
(63) Continuation of application No. PCT/JP2010/064208, filed on Aug. 24, 2010.

(30) Foreign Application Priority Data
Aug. 26, 2009 (JP) 2009-196039

(51) Int. Cl. G02F 1/1343; H01L 21/441; H01L 29/786

(52) U.S. Cl. 349/139; 257/43; 438/104; 257/E29.296; 257/E21.477

(57) ABSTRACT

Disclosed is an electrode film which does not exfoliate from, or diffuse into, an oxide semiconductor or an oxide thin film. An electrode layer comprises a highly adhesive barrier film being a Cu—Mg—Al thin film and a copper thin film; and an oxide semiconductor and an oxide thin film contact with the highly adhesive barrier film. With the highly adhesive barrier film having magnesium in a range of at least 0.5 at % but at most 5 at % and aluminum at least 5 at % but at most 15 at % when the total number of atoms of copper, magnesium, and aluminum is 100 at %, the highly adhesive barrier film has both adhesion and barrier properties. The electrode layer is suitable because a source electrode layer and a drain electrode layer contact the oxide semiconductor layer. A stopper layer having an oxide may be provided on a layer under the electrode layer.

This application is a continuation of International Application No. PCT/JP2010/064208, filed on Aug. 24, 2010, which claims priority to Japan Patent Application No. 2009-196039, filed on Aug. 26, 2009. The contents of the prior applications are herein incorporated by reference in their entireties.

### BACKGROUND OF THE INVENTION

1. Field of the Invention

The present invention is generally related to the field of wiring films used in micro semiconductor devices, and in particular, to the technical field of electrode layers which are in contact with an oxide semiconductor.

2. Description of the Background Art

Electronic products which have been manufactured in recent years (such as, FPDs (flat panel displays) and thin-film solar cells) require that transistors be disposed uniformly on a wide substrate, which is the reason that (hydrogenated) amorphous silicon or the like, which can form semiconductor layers with uniformity in property on a large-area substrate, are used.

Although amorphous silicon can be formed at low temperatures and does not negatively affect other materials, amorphous silicon has a drawback of being low in mobility, which leads to directing attention to oxide semiconductors capable of forming a thin film having high mobility formed on a large-area substrate at a low temperature.

On the other hand, low resistance copper thin films are recently being used in semiconductor integrated circuits and electrodes and wiring of transistors in FPDs in order to increase the transmission speed of digital signals and reduce the power consumption by reductions in power losses.

However, copper thin films exhibit poor adhesion to oxide semiconductors and oxide thin films; and copper atoms, which are the constituents of copper thin films, may diffuse into the oxide semiconductors and the oxide thin films, resulting in reduction in reliability.

In particular, if an oxide semiconductor and a copper thin film contact each other or an interlayer insulating film made of an oxide and a copper thin film contact each other, the diffusion of copper atoms into the oxide can cause a major problem.

In this case, it is necessary to provide an auxiliary film, which has a barrier property against diffusion and an adhesion property for increasing the adhesive strength of copper wiring, between the copper thin film and the semiconductor or insulating film or the like that contacts the copper thin film. For example, a TiN film or a W film or the like can be used as the auxiliary film.

Due to the difficulty in dry etching of a copper thin film, wet etching method is generally used; however, since etchants used for copper thin films and used for auxiliary film are not the same, a wiring film having a two-layer structure of the auxiliary film and the copper thin film cannot be etched in one etching step.

For this reason, an auxiliary film which has a barrier property and an adhesion property and can be etched by the same etchant as a copper thin film is desired.

See, Japanese Application Publication No. 2009-99847 and Japanese Application Publication No. 2007-250982.

### SUMMARY OF THE INVENTION

The present invention was created to overcome the above inconvenience of the prior arts, and an object thereof is to provide an electrode film which has high adhesion and from which copper atoms do not diffuse into an oxide semiconductor or an oxide thin film.

In order to solve the above problem, the present invention is directed to a semiconductor device having an oxide semiconductor layer; and an electrode layer contacting the oxide semiconductor layer. The electrode layer includes a highly adhesive barrier film contacting the oxide semiconductor layer, and a copper thin film contacting the highly adhesive barrier film. The highly adhesive barrier film includes copper, magnesium, and aluminum, with the magnesium being included in a range of at least 0.5 at % but at most 5 at %, and the aluminum being included in a range of at least 5 at % but at most 15 at %, when the total number of atoms of copper, magnesium, and aluminum is 100 at %.

The present invention is also directed to a semiconductor device. The semiconductor device is a transistor with the electrode layer having a source electrode layer and a drain electrode layer being separated from each other, the source electrode layer and the drain electrode layer contacting a source region and a drain region of the oxide semiconductor layer, respectively; and a gate electrode layer being disposed in a channel region between the source region and the drain region with a gate insulating film therebetween.

The present invention is also directed to a semiconductor device, in which an insulating film having an oxide is disposed on the oxide semiconductor layer, the source electrode layer and the drain electrode layer are disposed on the surface of the insulating film, and the highly adhesive barrier film of the source electrode layer and the drain electrode layer is disposed on an inner peripheral surface of a connection hole of the insulating film formed on the source region and the drain region.

The present invention is directed to a liquid crystal display device having the above-described semiconductor device, a pixel electrode, a liquid crystal disposed on the pixel electrode, and an upper electrode positioned on the liquid crystal. The pixel electrode is electrically connected to the electrode layer.

The present invention is directed to a method for producing a semiconductor device having an oxide semiconductor layer, and an electrode layer contacting the oxide semiconductor layer. The electrode layer includes a highly adhesive barrier film contacting the oxide semiconductor layer, and a copper thin film which contacts the highly adhesive barrier film. The highly adhesive barrier film includes copper, magnesium, and aluminum; and the magnesium is included in a range of at least 0.5 at % but at most 5 at %, and the aluminum is included in a range of at least 5 at % but at most 15 at %, when the total number of atoms of copper, magnesium, and aluminum is 100 at %. The method comprises the steps of: forming an oxide thin film on the surface of the oxide semiconductor layer; forming a stopper layer having the oxide thin film by partially removing the oxide thin film; exposing the oxide semiconductor layer at the portions from which the oxide thin film is removed; and forming the electrode layer by forming the highly adhesive barrier film contacting the surface of the exposed oxide semiconductor layer on the stopper layer, a source region, and a drain region, and by forming the copper thin film on the highly adhesive barrier film.

The present invention is also a method for producing a semiconductor device, which further includes the steps of: forming a gate insulating film on a channel region between the source region and the drain region of the oxide semiconductor layer; disposing a gate electrode layer on the gate insulating film; and forming the highly adhesive barrier film of the electrode layer so as to contact the source region and the drain region, with the source region and the drain region of the oxide semiconductor layer being exposed.

### EFFECTS OF THE INVENTION

The highly adhesive barrier film of the electrode film has a high adhesion property and a high barrier property to the oxide semiconductor layer, which enables the electrode film to be used in a source electrode and a drain electrode.

Even when a stopper layer composed of an oxide is provided as an etching stopper, the adhesion property and the barrier propriety are high with respect to the stopper layer and the insulating film composed of an oxide, so that etching using a stopper layer can be carried out.

Since the copper thin film contacts the interlayer insulating film and the gate insulating film via the highly adhesive barrier film, even on the inner peripheral surface of the connection hole formed on the interlayer insulating film and the gate insulating film, copper atoms do not diffuse into the gate insulating film or the interlayer insulating film.

The copper thin film and the highly adhesive barrier film can be etched with the same etchant.

### BRIEF DESCRIPTION OF THE DRAWINGS

FIGS. 1(a) to 1(c) show a process chart (1) for illustrating the process for producing a transistor in the first example of the present invention.

FIGS. 2(a) to 2(c) show a process chart (2) for illustrating the process for producing a transistor in the first example of the present invention.

FIGS. 3(a) to 3(c) show a process chart (3) for illustrating the process for producing a transistor in the first example of the present invention.

FIGS. 4(a) and 4(b) show a process chart (4) for illustrating the process for producing a transistor of the first example of the present invention.

FIG. 5 is a cross-sectional view for illustrating a transistor of a first example of the present invention and a liquid crystal display device of the present invention.

FIGS. 6(a) to 6(c) show a process chart for illustrating the process for producing a transistor in the second example of the present invention.

FIG. 7 is a cross-sectional view for illustrating a transistor in the third example of the present invention.

### DETAILED DESCRIPTION OF THE PREFERRED EMBODIMENTS

### Best Mode for Carrying Out the Invention

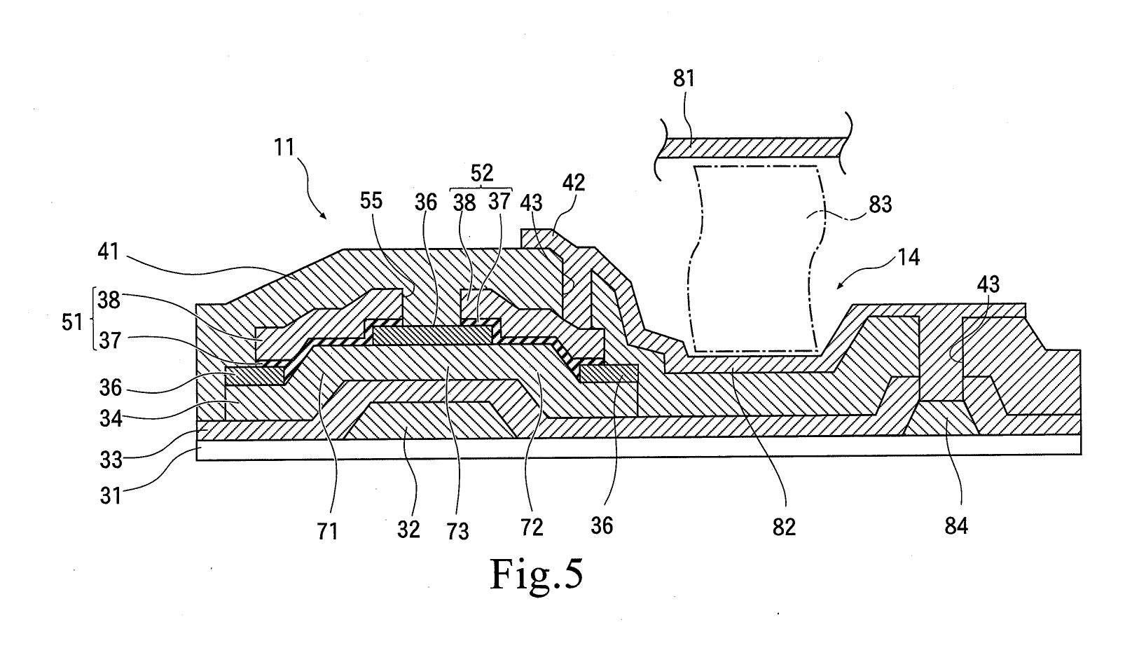

FIG. 5 is a liquid crystal display device of the embodiment of the present invention, and shows a cross-sectional view of a transistor 11 of the first example of the present invention together with a liquid crystal display part.

To explain the transistor 11, in the transistor 11, an elongated gate electrode layer 32 is disposed on the surface of a glass substrate 31, and a gate insulating film 33 is disposed at least across the width direction on the gate electrode layer 32.

An oxide semiconductor layer 34 is disposed on the gate insulating film 33. On the part of the oxide semiconductor layer 34 that is positioned on the gate electrode layer 32, a source electrode layer 51 and a drain electrode layer 52 are formed at both ends in the width direction of the gate insulating film 33. A concavity 55 is provided between the source electrode layer 51 and the drain electrode layer 52; and the source electrode layer 51 and the drain electrode layer 52 are separated by this concavity 55 and configured so that different voltages can be applied to each.

Reference numeral 36 is a stopper layer. When the concavity 55 is formed by etching to separate the source electrode layer 51 and the drain electrode layer 52, the etching solution is prevented from contacting the oxide semiconductor layer 34 by the stopper layer 36.

While a protective film 41 is formed on the source electrode layer 51, on the drain electrode layer 52, and on the concavity 55 therebetween, the stopper layer 36 is positioned between the oxide semiconductor layer 34 and the protective film 41.

When a gate voltage is applied to the gate electrode layer 32 in a state in which a voltage is applied between the source electrode layer 51 and the drain electrode layer 52, a channel layer of a conductivity type opposite to the conductivity type of the oxide semiconductor layer 34 (or a low resistance channel layer of an identical conducting type) is formed on a portion facing the gate electrode layer 32 within the oxide semiconductor layer 34 via the gate insulating film 33, a portion of the oxide semiconductor layer 34 which contacts the source electrode layer 51 and a portion of the oxide semiconductor layer 34 which contacts the drain electrode layer 52 are connected at low resistance by the channel layer 73 (or low resistance layer), thereby the source electrode layer 51 and the drain electrode layer 52 are electrically connected, and the transistor 11 conducts.

If the application of the gate voltage is stopped, the channel layer 73 (or low resistance layer) disappears, and the resistance between the source electrode layer 51 and the drain electrode layer 52 becomes high, thereby electrically separated.

A pixel electrode 82 is disposed in a liquid crystal display region 14, and a liquid crystal 83 is disposed on the pixel electrode 82. An upper electrode 81 is positioned on the liquid crystal 83; and when a voltage is applied between the pixel electrode 82 and the upper electrode 81, the polarized nature of light passing through the liquid crystal 83 is changed, and the passage of a polarizing filter is controlled.

The pixel electrode 82 is electrically connected to the source electrode layer 51 or the drain electrode layer 52; and the voltage application to the pixel electrode 82 is initiated and completed by switching the transistor 11 ON/OFF.

The pixel electrode 82 is comprised of a portion of a wiring layer 42 connected to the drain electrode layer 52. The wiring layer 42 is a transparent conductive layer composed of ITO, and the wiring layer 42 is formed on the glass substrate 31 as is the case with the gate electrode layer 32 and is connected to a wiring layer 84 formed of a thin film being identical with the thin film constituting the gate electrode layer 32.

The process for producing the transistor 11 will now be explained below.

For making the transistor 11, first of all, a first conductive thin film is formed on the glass substrate 31 by a method for forming a thin film under a vacuum (such as, a sputtering method or a deposition method), and then the first conductive thin film is patterned to form the gate electrode layer 32. A thin film or the like having high adhesion to glass (such as, a metal or polysilicone) can be used for the first conductive thin film.

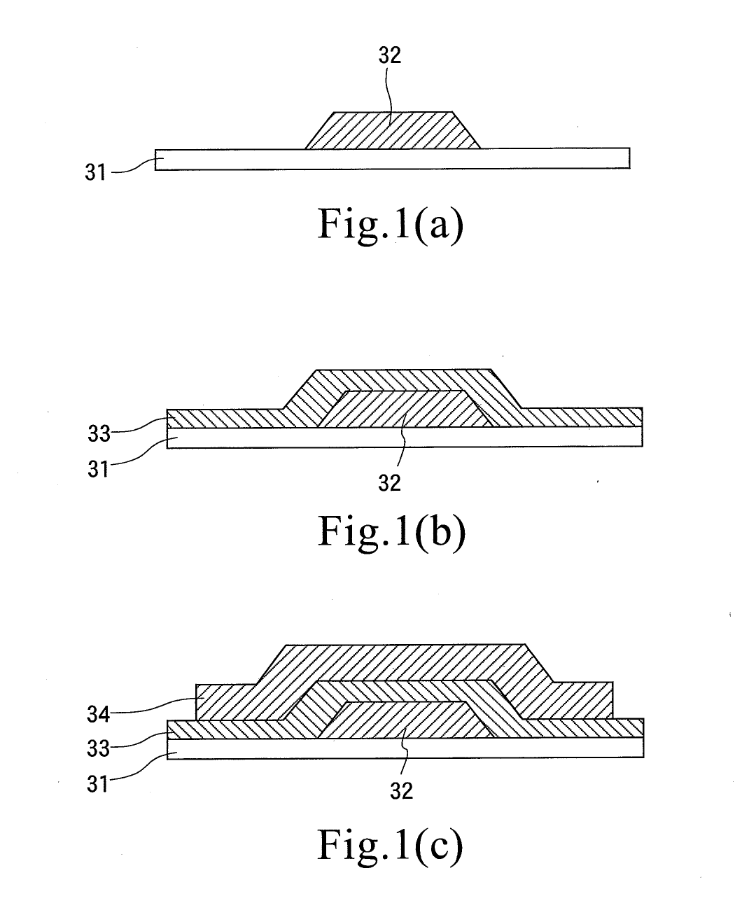

Reference numeral 32 in FIG. 1(a) denotes the gate electrode layer formed on the glass substrate 31.

When the gate electrode layer 32 is formed by patterning, the glass substrate surface is exposed except for the portion where the gate electrode layer 32 is positioned; and a gate insulating film 33 of SiO₂, SiNₓ, or the like is formed on the surface of the glass substrate 31 and the gate electrode layer 32, as shown in FIG. 1(b). The gate insulating film 33 is patterned as necessary.

Then, a thin film of an oxide semiconductor is formed on the gate insulating film 33 and patterned, as shown in FIG. 1(c), to form an oxide semiconductor layer 34 formed of the patterned thin film of an oxide semiconductor.

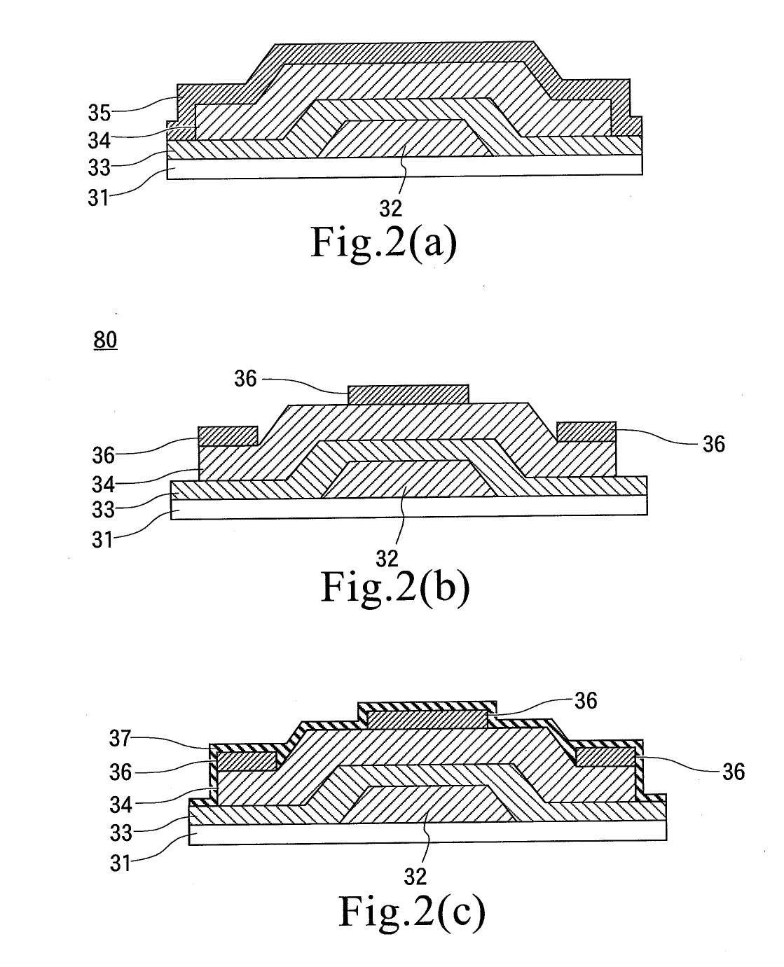

Next, as shown in FIG. 2(a), an oxide insulating thin film 35 is formed across the surface of the oxide semiconductor layer 34 and the surface of the gate insulating film 33 exposed at least between the oxide semiconductor layer 34; and by patterning the oxide insulating thin film 35, as shown in FIG. 2(b), a stopper layer 36 formed of an oxide insulating thin film is formed.

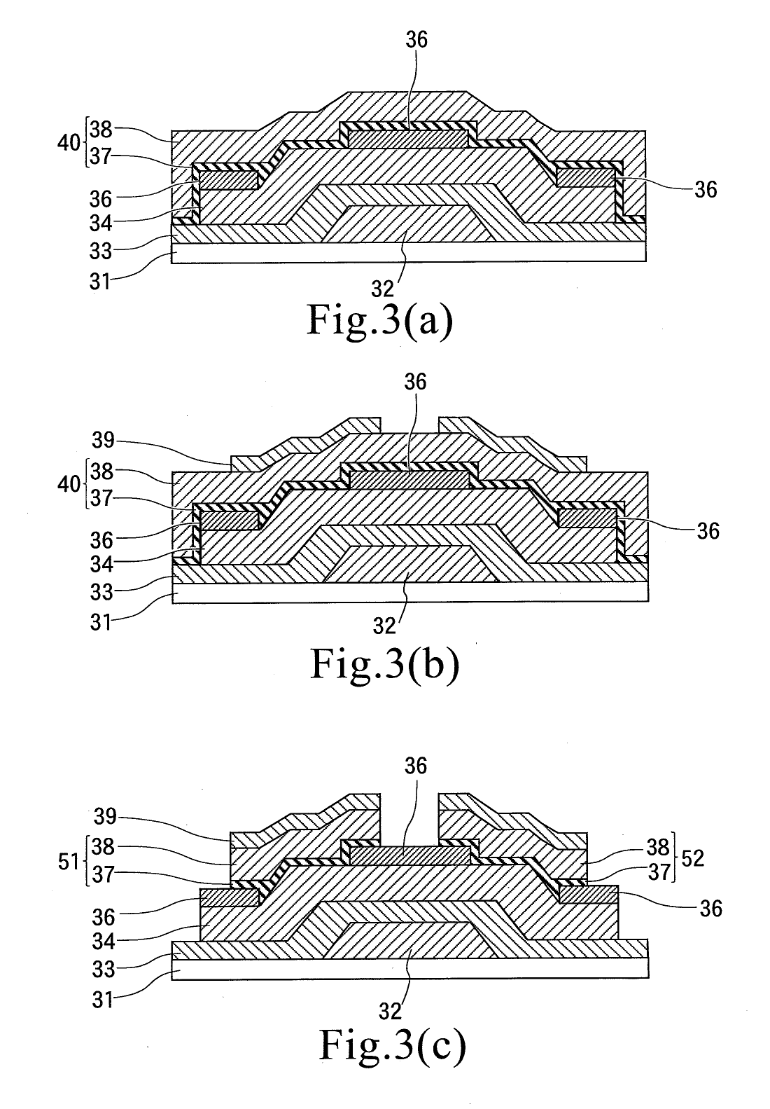

A source region 71 and a drain region 72, located spaced apart from each other at both ends in the width direction of the gate electrode layer 32, are placed on the oxide semiconductor layer 34; the stopper layer 36 is located so as to expose the source region 71 and the drain region 72 on the surface of the oxide semiconductor layer 34 but cover the surface of the other portions. In this state, first, a highly adhesive barrier film 37 is formed at least on the stopper layer 36 and the exposed portions of the oxide semiconductor layer 34 by the sputtering method; and next, as shown in FIG. 3(a), a copper thin film 38 is formed on the surface of the highly adhesive barrier film 37 in order to form an electrode layer 40 by the highly adhesive barrier film 37 and the copper thin film 38.

When forming the copper thin film 38, since oxygen gas is not introduced into the sputtering atmosphere and copper oxide is not incorporated into the copper thin film 38, a copper thin film 38 having low resistance is obtained.

In the present invention, the highly adhesive barrier film is a thin film composed of Cu—Mg—Al, and to explain the process for forming the highly adhesive barrier film, a processing object 80 shown in FIG. 2(b), with the surface of the stopper layer 36 and the surface of the oxide semiconductor layer 34 in the portions of the source region 71 and the drain region 72 being exposed, is transported into a sputter device; and when a target composed of a Cu—Mg—Al alloy is sputtered to make the sputtering particles reach the surface of the processing object 80, the highly adhesive barrier film 37, which contacts the surface of the stopper layer 36 and the surface of the oxide semiconductor layer 34 in the exposed portions of the source region 71 and the drain region 72, is formed.

The highly adhesive barrier film 37 has high adhesion to oxides; and the electrode layer 40 does not exfoliate from the thin film of an oxide semiconductor or the thin film of an oxide. Further, the adhesion between the highly adhesive barrier film 37 and the copper thin film 38 is also high; and thus, the copper thin film 38 does not exfoliate from the highly adhesive barrier film 37.

The highly adhesive barrier film 37 is formed on the surface of the stopper layer 36, which is an oxide composed of SiO₂, and the surface of the oxide semiconductor layer 34, and the copper thin film 38 is formed on the surface of the highly adhesive barrier film 37. Therefore, the copper thin film 38 does not exfoliate from the stopper layer 36 and the oxide semiconductor layer 34.

Further, the highly adhesive barrier film 37 has a barrier function against copper atoms, which prevents copper atoms from diffusing from the highly adhesive barrier film 37 into the oxide semiconductor layer 34; also, since the highly adhesive barrier film 37 is positioned between the copper thin film 38 and the oxide semiconductor layer 34, diffusion of copper atoms within the copper thin film 38 is stopped by the highly adhesive barrier film 37; thus, the diffusion of copper atoms into the oxide semiconductor layer 34 is prevented.

After the highly adhesive barrier film 37 and the copper thin film 38 are formed, a resist film is formed on the surface of the copper thin film 38 and then the resist film is patterned to have a resist film 39 being disposed, as shown in FIG. 3(b), at positions on the surface of the copper thin film 38 above the source region 71 and the drain region 72.

When immersed in an etching solution which dissolves a metal such as copper in this state, the copper thin film 38 exposed among the resist film 39 and the highly adhesive barrier film 37 positioned directly below the exposed portions of the copper thin film 38 are etched by the etching solution, leaving only the portion on the source region 71 and the portion on the drain region 72 which are covered by the resist film 39, which results in such a way that, as shown in FIG. 3(c), a source electrode layer 51 is formed by the highly adhesive barrier film 37 being left on the source region 71 and the copper thin film 38, and a drain electrode layer 52 is formed by the copper thin film 38 and the highly adhesive barrier film 37 left on the drain region 72. The source electrode layer 51 and the drain electrode layer 52 are spaced apart from each other; a portion of the source electrode layer 51 is positioned on one end of the gate electrode layer 32; and a portion of the drain electrode layer 52 is positioned on the other end of the gate electrode layer 32. The edge portions of the source electrode layer 51 and the edge portions of the drain electrode layer 52 are located on top of the stopper layer 36.

A channel region 73 is located between the source region 71 and the drain region 72 of the oxide semiconductor layer 34; and the gate electrode layer 32 is located in a position facing the channel region 73 with the gate insulating film 33 therebetween. In this state, the transistor 11 is formed of the gate insulating film 33 and the gate, source, and drain electrode layers 32, 51, 52.

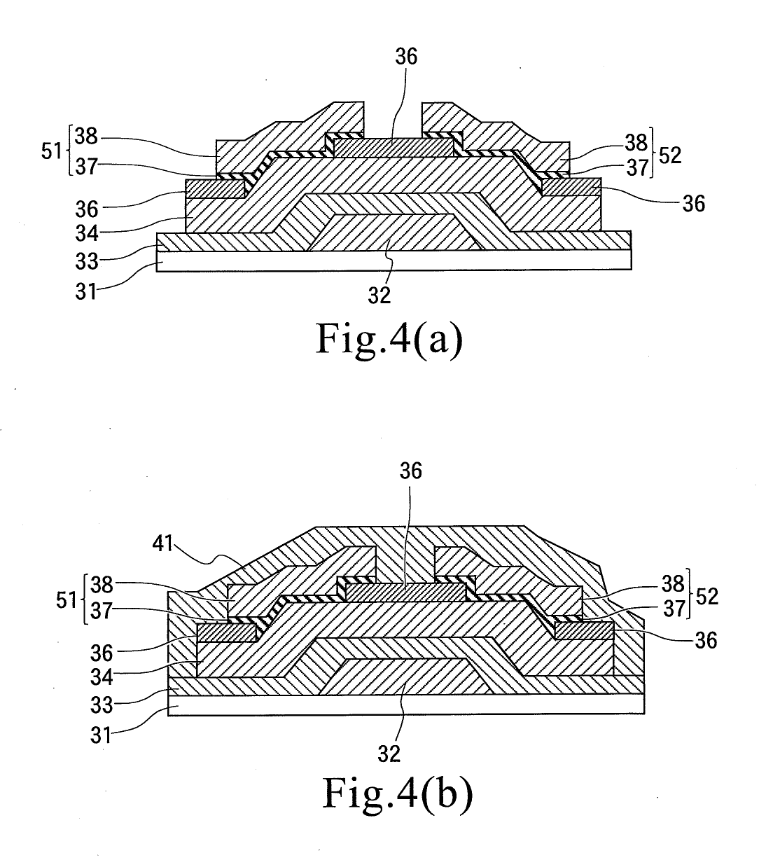

Subsequently, as shown in FIG. 4(a), the resist film 39 is removed to form a protective film 41 composed of an insulating film of SiNₓ, SiO₂ or the like, as shown in FIG. 4(b); as shown in FIG. 5, a connection hole 43 (such as, a via hole or a contact hole) is formed in the protective film 41; and by connecting the source electrode layer 51, the drain electrode layer 52 or the like and electrode layers of other elements, exposed at the bottom of the connection hole 43, with the patterned wiring layer 42, the gate, source, and drain electrode layers 32, 51, 52 are enabled to be applied a voltage; subsequently, the transistor 11 can operate. (The liquid crystal 83 and the upper electrode 81 are disposed later in the process.)

In the above explanation, an etching solution which erodes the oxide semiconductor layer 34 is used to etch the copper thin film 38 and the highly adhesive barrier film 37, preventing the etching solution from contacting the oxide semiconductor layer 34 due to the stopper layer 36; however, when an etching solution, which does not erode the oxide semiconductor layer 34 is used, the oxide semiconductor layer 34 can contact the etching solution and the stopper layer 36 is unnecessary.

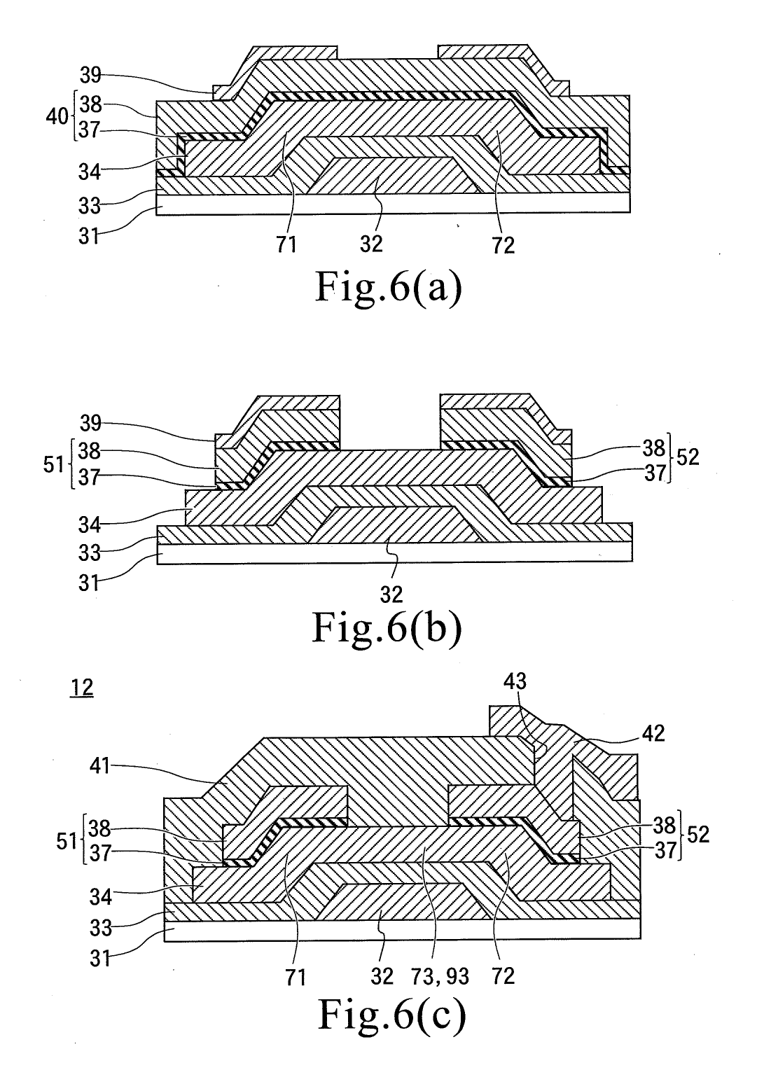

FIG. 6(c) shows a part of a liquid crystal display device, and a transistor 12 which does not have the stopper layer 36. The liquid crystal display region is omitted from the figure.

FIG. 6(a) illustrates a state in which, after the patterned oxide semiconductor layer 34 is formed on the gate insulating film 33, the highly adhesive barrier film 37 and the copper thin film 38 are formed in layers in this order, and the resist film 39 is disposed on the surface of the copper thin film 38 above the source region 71 and the surface of the copper thin film 38 above the drain region 72 of the oxide semiconductor layer 34; in such a state, by immersing in the etching solution that does not erode the oxide semiconductor layer 34, the portions of the copper thin film 38 and the highly adhesive barrier film 37, which are not covered by the resist film 39, are etched and removed.

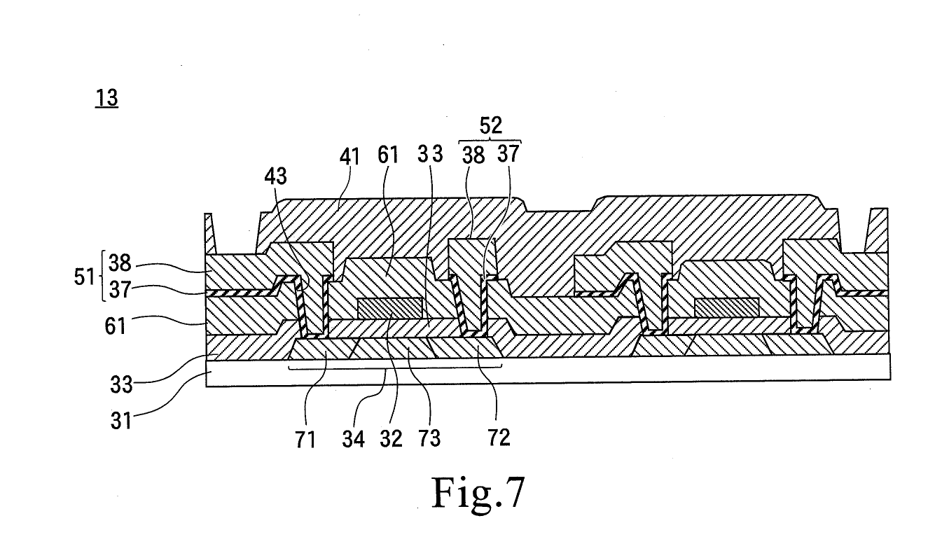

At this time, the oxide semiconductor layer 34 and the etching solution contact each other, but the oxide semiconductor layer 34 is not eroded, so that after the removal of the resist layer 39, as shown in FIG. 6(c), by forming the connection hole 43 in the protective film 41, and connecting the wiring to the source electrode layer 51 or the drain electrode layer 52, the transistor 12 which does not have the stopper layer 36 is enabled to operate. From the glass substrate 31 side, the gate electrode layer 32, the gate insulating film 33, the oxide semiconductor layer 34, and the source and drain electrode layers 51, 52 are positioned in this order to form a bottom-gate transistor; however, as shown in FIG. 7, a top-gate transistor 13 can also be formed.

The transistor 13 has the oxide semiconductor layer 34, which is partially formed on the glass substrate 31, and the gate insulating film 33, which is formed on the oxide semiconductor layer 34 and the glass substrate 31 which is exposed among the oxide semiconductor layer 34.

The source regions 71 and the drain regions 72 are formed respectively on each ends of the oxide semiconductor layers 34, and between the source region 71 and the drain region 72 is made as the channel region 73 in which a channel layer is formed.

The gate electrode layer 32 is disposed on the portion of the gate insulating film 33 on the channel region 73; and an interlayer insulating layer 61, which is a thin film composed of an oxide, is disposed on the gate insulating film 33 so as to cover the gate electrode layer 32.

Connection holes 43 are formed in the portions of the gate insulating film 33 and the interlayer insulating layer 61 on the source region 71 and on the drain region 72. The highly adhesive barrier film 37 and the copper thin film 38 are formed in layers in this order on the interlayer insulating layer 61 with the surface of the source region 71 and the surface of the drain region 72 being exposed at the bottom of the connection holes 43, so as to configure an electrode layer having a two-layer structure.

The electrode layer is patterned to form the source electrode layer 51, in which the highly adhesive barrier film 37 contacts the surface of the source region 71, and the drain electrode layer 52, in which the highly adhesive barrier film 37 contacts the surface of the drain region 72, being separated from the source electrode layer 52, so as to configure the transistor.

When a gate voltage is applied to the gate electrode layer 32 with a voltage being applied to the source electrode layer 51 and the drain electrode layer 52, a low resistance channel layer of a conductivity type that is the same or opposite to the conductivity type of the channel region 73 is formed within the channel region 73, thereby establishing an electrical continuity between the source region 71 and the drain region 72.

The protective film 41 is formed on the source electrode layer 51 and the drain electrode layer 52 and the interlayer insulating layer 61 exposed therebetween.

Also in this transistor 13, the copper thin film 38 does not directly contact an insulating film composed of an oxide such as the interlayer insulating layer 61 and the oxide semiconductor layer 34, but contacts the insulating film via the highly adhesive barrier film 37. The copper film 38 does not exfoliate due to the high adhesion of the highly adhesive barrier film 37; and the copper atoms within the copper thin film 38 and within the highly adhesive barrier film 37 do not diffuse into the insulating film or the semiconductor region due to the barrier property of the highly adhesive barrier film 37.

### EMBODIMENTS

A target was made with Cu (copper) being a main component, and with Mg (magnesium) and Al (aluminum) being included in desired proportions; the target was sputtered to form a highly adhesive barrier film composed of Cu—Mg—Al, having the same composition as the target, on the surface of an insulating thin film composed of an oxide (for instance, an SiO₂ thin film in this embodiment) or an oxide semiconductor thin film (for instance, an IGZO film: InGaZnO in this embodiment); and a pure copper thin film was then formed on the formed highly adhesive barrier film to form an electrode layer formed of the highly adhesive barrier film and the pure copper thin film.

The adhesion property and barrier property of highly adhesive barrier films, having the different addition proportions of Mg and Al, were evaluated.

The evaluation results of the oxide semiconductor are shown in Table 1; and the evaluation results of the insulating thin film are shown in Table 2.

TABLE 1
Measurement Results of Adhesion and Barrier Properties to Oxide Semiconductor

| | | | | | | Barrier |
|---|---|---|---|---|---|---|
| | | | | Adhesion Property | | Property |
| | | | | (Tape test) | | (AES) |
| Composition of | Mg | Al | Possibility | IGZO Film | | IGZO Film |
| Highly Adhesive | Content | Content | for Target | Without | After | After |
| Barrier Film | X at % | Y at % | Production | Annealing | Annealing | Annealing |
| Cu | — | — | ◯ | X | X | X |
| Cu-X at % Mg | 0.5 | — | ◯ | X | X | X |
| | 2.5 | — | ◯ | ◯ | X | X |
| | 5 | — | X | — | — | — |
| Cu-Y at % Al | — | 5 | ◯ | ◯ | X | X |
| | — | 10 | ◯ | ◯ | X | X |
| | — | 15 | ◯ | ◯ | X | X |
| | — | 20 | X | — | — | — |
| Cu-X at % Mg-Y at % Al | 0.5 | 3 | ◯ | X | X | X |
| | | 5 | ◯ | ◯ | ◯ | ◯ |
| | | 10 | ◯ | ◯ | ◯ | ◯ |
| | | 15 | ◯ | ◯ | ◯ | ◯ |
| | | 20 | X | — | — | — |
| | 2.5 | 3 | ◯ | ◯ | X | X |
| | | 5 | ◯ | ◯ | ◯ | ◯ |
| | | 10 | ◯ | ◯ | ◯ | ◯ |
| | | 15 | ◯ | ◯ | ◯ | ◯ |
| | | 20 | X | — | — | — |
| | 5 | 3 | X | — | — | — |
| | | 5 | ◯ | ◯ | ◯ | ◯ |
| | | 10 | ◯ | ◯ | ◯ | ◯ |
| | | 15 | ◯ | ◯ | ◯ | ◯ |
| | | 20 | X | — | — | — |
| | 10 | 3 | X | — | — | — |
| | | 5 | X | — | — | — |
| | | 10 | X | — | — | — |
| | | 15 | X | — | — | — |
| | | 20 | X | — | — | — |

“After Annealing” is a measurement result after heating for one hour at 400° C. under a vacuum atmosphere.

TABLE 2
Measurement Results of Adhesion and Barrier Properties to Insulating Thin Film Composed of Oxide

| | | | | Adhesion Property | | | | Barrier Property | |
|---|---|---|---|---|---|---|---|---|---|
| | | | | (Tape test) | | | | (AES) | |
| | | | | SiH₄-based | | TEOS-based | | SiH₄-based | TEOS-based |
| Composition of | Mg | Al | Possibility | SiO₂ Film | | SiO₂ Film | | SiO₂ Film | SiO₂ Film |
| Highly Adhesive | Content | Content | for Target | Without | After | Without | After | After | After |
| Barrier Film | X at % | Y at % | Production | Annealing | Annealing | Annealing | Annealing | Annealing | Annealing |
| Cu | — | — | ◯ | X | X | X | X | X | X |
| Cu-X at % Mg | 0.5 | — | ◯ | X | X | X | X | X | X |
| | 2.5 | — | ◯ | ◯ | X | ◯ | X | X | X |
| | 5 | — | X | — | — | — | — | — | — |
| Cu-Y at % Al | — | 5 | ◯ | X | X | X | X | X | X |
| | — | 10 | ◯ | ◯ | X | ◯ | X | X | X |
| | — | 15 | ◯ | ◯ | X | ◯ | X | X | X |
| | — | 20 | X | — | — | — | — | — | — |
| Cu-X at % Mg-Y at % Al | 0.5 | 3 | ◯ | X | X | X | X | X | X |
| | | 5 | ◯ | ◯ | ◯ | ◯ | ◯ | ◯ | ◯ |
| | | 10 | ◯ | ◯ | ◯ | ◯ | ◯ | ◯ | ◯ |
| | | 15 | ◯ | ◯ | ◯ | ◯ | ◯ | ◯ | ◯ |
| | | 20 | X | — | — | — | — | — | — |
| | 2.5 | 3 | ◯ | ◯ | X | X | X | X | X |
| | | 5 | ◯ | ◯ | ◯ | ◯ | ◯ | ◯ | ◯ |
| | | 10 | ◯ | ◯ | ◯ | ◯ | ◯ | ◯ | ◯ |
| | | 15 | ◯ | ◯ | ◯ | ◯ | ◯ | ◯ | ◯ |
| | | 20 | X | — | — | — | — | — | — |
| | 5 | 3 | X | — | — | — | — | — | — |
| | | 5 | ◯ | ◯ | ◯ | ◯ | ◯ | ◯ | ◯ |
| | | 10 | ◯ | ◯ | ◯ | ◯ | ◯ | ◯ | ◯ |
| | | 15 | ◯ | ◯ | ◯ | ◯ | ◯ | ◯ | ◯ |
| | | 20 | X | — | — | — | — | — | — |
| | 10 | 3 | X | — | — | — | — | — | — |
| | | 5 | X | — | — | — | — | — | — |
| | | 10 | X | — | — | — | — | — | — |
| | | 15 | X | — | — | — | — | — | — |
| | | 20 | X | — | — | — | — | — | — |

“After Annealing” is a measurement result after heating for one hour at 400° C. under a vacuum atmosphere.

In Table 2, an insulating thin film composed of SiO₂ was formed on the glass substrate. The “SiH₄-based SiO₂ film” is a SiO₂ film formed on the glass substrate by a CVD method with the use of SiH₄ gas and N₂O gas as ingredients; and the “TEOS-based SiO₂ film” is an SiO₂ film formed by the CVD method with the use of TEOS and O₂ gas.

The numerical values in the “Mg Content” and the “Al Content” in Tables 1 and 2 are the proportion of the number of Mg atoms included (X at %) and the proportion of the number of Al atoms included (Y at %), when the total number of Cu atoms, Mg atoms, and Al atoms in the target or the highly adhesive barrier film is 100 at %, and “−” means that the content is zero.

In the column called “Possibility for Target Production”, the case in which the materials of Cu, Mg, and Al could be formed in the target was sorted to be encircled as “◯”, and refers to the case in which the materials could not be formed in the target was sorted to be marked with a cross as “X”.

In the evaluation in the column called “Adhesion”, an adhesive tape was applied to the surface of the pure copper thin film, and when the adhesive tape was torn off, the case in which the adhesive tape was exfoliated at the interface of the adhesive tape and the pure copper thin film was sorted to be encircled as “◯”, and the case in which there was breakage within the electrode layer, or the adhesive tape was exfoliated at the interface of the electrode layer and the insulating thin film or the oxide semiconductor, was sorted to be marked with a cross as “X”.

Regarding the barrier property, the presence or absence of diffusion of Cu atoms into the thin film composed of the oxide semiconductor contacting the highly adhesive barrier film or into the insulating thin film consisting of an oxide was measured by the analysis method of Auger electron spectroscopy; the case in which Cu was not detected was sorted to be encircled as “◯”; and the case in which Cu was detected was sorted to be marked with a cross as “X”.

From the measurement results listed in Tables 1 and 2, it can be seen that if both Mg and Al are not included, the adhesion and barrier properties are especially bad after annealing; and both the adhesion property and the barrier property are superior when the Mg content percentage is as least 0.5 at % and at most 5 at % and the Al content percentage is at least 5 at % and at most 15 at %. Accordingly, the highly adhesive barrier film 37, which is a thin film consisting of Cu—Mg—Al, in the above-described embodiments of the present invention is a conductive thin film in which the Mg content percentage is at least 0.5 at % and at most 5 at % and the Al content percentage is at least 5 at % and at most 15 at % when the total number of atoms of Cu, Mg, and Al is 100 at %.

The copper thin film 38 formed on the highly adhesive barrier film 37, contacting the highly adhesive barrier film 37, is a low resistance conductive thin film which has copper at a content percentage exceeding 50 at % when its total number of atoms is 100 at %.

The above-discussed oxide semiconductor was InGaZnO, but the present invention is not limited to this, and an oxide semiconductor (such as, ZnO and SnO₂₎ is also included.

Further, the insulating film composed of an oxide which contacts the highly adhesive barrier film 37 (the above-described stopper layer 36 is one example) was a SiO₂ film, but the present invention is not limited to this constitution, and the insulating film composed of an oxide also includes a thin film including an oxide. The insulating film of the present invention includes, for example, an SiON film, an SiOC film, an SiOF film, an Al₂O₃ film, a Ta₂O₅ film, an HfO₂ film, and a ZrO₂ film.

1. A semiconductor device, comprising:
an oxide semiconductor layer; and
an electrode layer contacting the oxide semiconductor layer,
wherein the electrode layer includes a highly adhesive barrier film contacting the oxide semiconductor layer, and a copper thin film contacting the highly adhesive barrier film, and
wherein the highly adhesive barrier film includes copper, magnesium, and aluminum, the magnesium being included in a range of at least 0.5 at % but at most 5 at %, and the aluminum being included in a range of at least 5 at % but at most 15 at %, when the total number of atoms of copper, magnesium, and aluminum is 100 at %.

2. The semiconductor device according to claim 1,
wherein the semiconductor device is a transistor with:
the electrode layer having a source electrode layer and a drain electrode layer being separated from each other,
the source electrode layer and the drain electrode layer contacting a source region and a drain region of the oxide semiconductor layer, respectively, and
a gate electrode layer being disposed in a channel region between the source region and the drain region with a gate insulating film therebetween.

3. The semiconductor device according to claim 2, wherein an insulating film having an oxide is disposed on the oxide semiconductor layer, the source electrode layer and the drain electrode layer are disposed on the surface of the insulating film, and the highly adhesive barrier film of the source electrode layer and the drain electrode layer are disposed on an inner peripheral surface of a connection hole of the insulating film formed on the source region and the drain region.

4. A liquid crystal display device, comprising the semiconductor device according to any of claim 1 to claim 3, a pixel electrode, a liquid crystal disposed on the pixel electrode, and an upper electrode positioned on the liquid crystal,
wherein the pixel electrode is electrically connected to the electrode layer.

5. A method for producing a semiconductor device having:
an oxide semiconductor layer having a source region and a drain region; and
an electrode layer contacting the oxide semiconductor layer;
the electrode layer having a highly adhesive barrier film contacting the oxide semiconductor layer, and a copper thin film contacting the highly adhesive barrier film;
the highly adhesive barrier film including copper, magnesium, and aluminum, and the magnesium being included in a range of at least 0.5 at % but at most 5 at %, and the aluminum being included in a range of at least 5 at % but at most 15 at %, when the total number of atoms of copper, magnesium, and aluminum being 100 at %,
the method comprising the steps of:
forming an oxide thin film on the surface of the oxide semiconductor layer,
forming a stopper layer having the oxide thin film by partially removing the oxide thin film,
exposing the oxide semiconductor layer at the portions from which the oxide thin film is removed,
forming the highly adhesive barrier film contacting on the stopper layer and the surface of the oxide semiconductor layer with the source region and the drain region being exposed thereon, and
forming the electrode layer by forming the copper thin film on the highly adhesive barrier film.

6. A method for producing a semiconductor device having:
an oxide semiconductor layer having a source region and a drain region; and
an electrode layer contacting the oxide semiconductor layer;
the electrode layer having a highly adhesive barrier film contacting the oxide semiconductor layer, and a copper thin film contacting the highly adhesive barrier film;
the highly adhesive barrier film including copper, magnesium, and aluminum, and the magnesium being included in a range of at least 0.5 at % but at most 5 at %, and the aluminum being included in a range of at least 5 at % but at most 15 at %, when the total number of atoms of copper, magnesium, and aluminum being 100 at %,
the method comprising the steps of:
forming a gate insulating film on a channel region between the source region and the drain region of the oxide semiconductor layer,
and
forming the highly adhesive barrier film of the electrode layer so as to contact the source region and the drain region, with the source region and the drain region of the oxide semiconductor layer being exposed.
